(19) United States
(12) Patent Application Publication
(10) Pub. No.: US 2007/0035674 A1
(43) Pub. Date: Feb. 15, 2007

(54) ACTIVE MATRIX DISPLAY WITH LARGER APERTURE

(76) Inventor: Yu-Chuan Shen, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,791

(22) Filed: Sep. 22, 2005

(30) Foreign Application Priority Data
Aug. 10, 2005 (TW) 94127109

(51) Int. Cl. G02F 1/136

(52) U.S. Cl. 349/42

(57) ABSTRACT

An active device array substrate comprising a substrate, a plurality of scan lines, a plurality of data lines and a plurality of active devices is provided. The scan lines, the data lines, and the active devices are disposed on the substrate. Each of the active devices is connected to one of the scan lines and one of the data lines and the surfaces of the active devices are not parallel to the surface of the substrate. Because surfaces of the active devices incline to the surface of the substrate, the projection areas of non-transparency of the active devices on the surface of the substrate could be reduced. Moreover, this active device array substrate could be applied to a liquid crystal display panel and other active matrix flat panel display to obtain a better pixel aperture.

### CROSS-REFERENCE TO RELATED APPLICATION

This application claims the priority benefit of Taiwan application serial no. 94127109, filed on Aug. 10, 2005. All disclosure of the Taiwan application is incorporated herein by reference.

### BACKGROUND OF THE INVENTION

1. Field of the Invention

The present invention relates to a flat panel display, a liquid crystal display (LCD) panel and an active device array substrate. More particularly, the present invention relates to a flat panel display, a liquid crystal display panel and an active device array substrate with a larger aperture.

2. Description of the Related Art

With the rapid progress in optical/electronic techniques and means of fabricating semiconductor devices, flat panel displays (FPD) including liquid crystal displays (LCD), organic light-emitting diodes (OLED), plasma display panels (PDP) and so on have become the mainstream display products in the electronics industry. The method for driving the pixels of a flat panel display can be roughly categorized as passive or active. In general, the active flat panel display has a better display quality and thin film transistor (TFT) is currently the most commonly used active device inside a flat panel display.

FIG. 1A is a top view of a conventional active device array substrate and FIG. 1B is a schematic cross-sectional view along line I-I′ of FIG. 1A. As shown in FIGS. 1A and 1B, the conventional active device array substrate 100 is fabricated using a thin film deposition process in which a plurality of scan lines 120, a plurality of data lines 130 and a plurality of surface thin film transistors 140 are formed on the substrate. Each thin film transistor 140 is electrically connected to one of the scan lines 120 and one of the data lines 130 so that the thin film transistor 140 can be driven through the data line 130 and the scan line 120. However, the thin film transistors 140 are not completely transparent. Hence, the aperture of the flat panel display will be reduced when the active device array substrate 100 is applied to a flat panel display.

### SUMMARY OF THE INVENTION

Accordingly, at least one objective of the present invention is to provide an active device array substrate suitable for reducing the projection areas of non-transparency of the active devices on the substrate.

At least a second objective of the present invention is to provide a flat panel display having a larger pixel aperture.

At least a third objective of the present invention is to provide a liquid crystal display panel having a larger pixel aperture.

To achieve these and other advantages and in accordance with the purpose of the invention, as embodied and broadly described herein, the invention provides an active device array substrate comprising a substrate, a plurality of scan lines, a plurality of data lines and a plurality of active devices. The scan lines, the data lines, and the active devices are disposed on the substrate. Each active device is electrically connected to one of the scan lines and one of the data lines. Furthermore, the surfaces of active devices are not parallel to the surface of the substrate.

The present invention also provides a flat panel display comprising the aforesaid active device array substrate and a plurality of display elements. The display elements are disposed on the active device array substrate and electrically connected to corresponding active devices. The display elements can be organic light-emitting display (OLED) devices.

The present invention also provides a liquid crystal display panel comprising the aforesaid active device array substrate, a plurality of pixel electrodes, an opposing substrate, a common electrode layer and a liquid crystal layer. The pixel electrodes are disposed on the active device array substrate and electrically connected to corresponding active devices. The opposing substrate is disposed above the active device array substrate and the common electrode layer is disposed on the surface of the opposing substrate facing the active device array substrate. The liquid crystal layer is disposed between the active device array substrate and the opposing substrate and located between the common electrode layer and the pixel electrodes.

In the aforesaid flat display, liquid crystal display panel and active device array substrate, the active devices are partially or totally disposed within the areas occupied by the scan lines or the data lines. Furthermore, the active device can have a strip-shape. In addition, the active devices can be thin film transistors.

The aforesaid liquid crystal display panel may further include a black matrix disposed between the common electrode layer and the opposing substrate and located above the active device, the scan lines and the data lines.

In brief, the active devices in the flat display, the liquid crystal display panel and the active device array substrate of the present invention have smaller projection area on the surface of the substrate. As a result, the pixel aperture of the liquid crystal display panel and other flat displays using the active device array substrate is increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view showing part of a conventional active device array substrate.

FIG. 1B is a schematic cross-sectional view along line I-I′ of FIG. 1A.

FIG. 2A is a top view showing part of an active device array substrate according to one embodiment of the present invention.

FIG. 2B is a schematic cross-sectional view along line II-II′ of FIG. 2A.

FIG. 3 is a diagram illustrating the principles behind the reduction in the projection areas of non-transparency of an active device on an active device array substrate according to the present invention.

FIGS. 4 and 5 show part of the top views of two different active device array substrate according to the present invention.

FIG. 6 shows part of the top view of a flat panel display according to one embodiment of the present invention.

FIG. 7 shows a schematic cross-sectional view of part of a liquid crystal display panel according to one embodiment of the present invention.

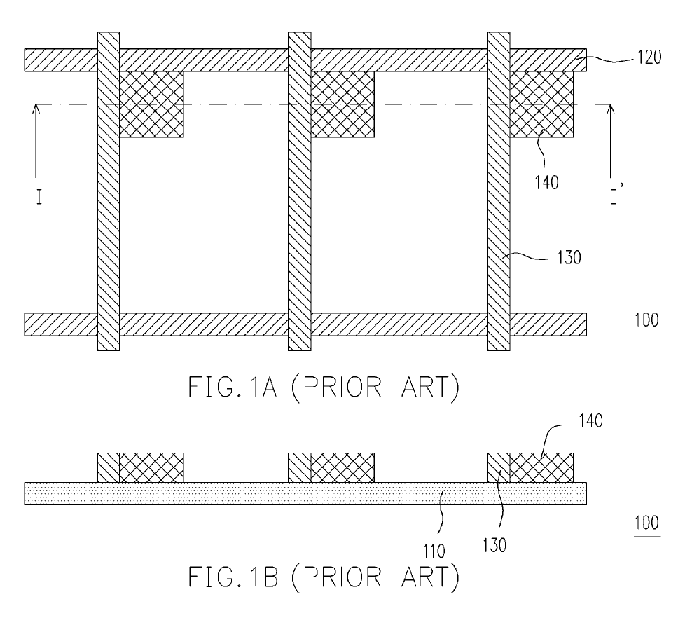

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

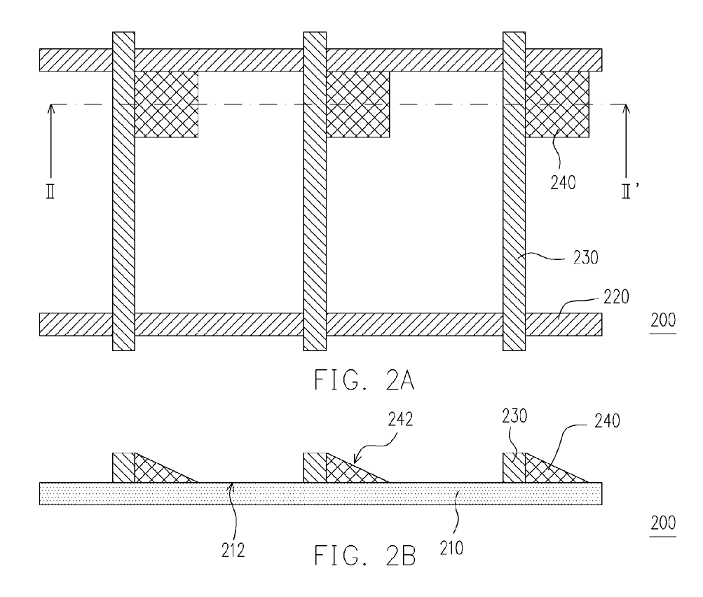

FIG. 2A is a top view showing part of an active device array substrate according to one embodiment of the present invention. FIG. 2B is a schematic cross-sectional view along line II-II′ of FIG. 2A. As shown in FIGS. 2A and 2B, the active device array substrate 200 in the present embodiment comprises a substrate 210 (only shown in FIG. 2B), a plurality of scan lines 220 (only shown in FIG. 2A), a plurality of data lines 230 and a plurality of active devices 240. The substrate 210 could be a glass substrate used by organic light-emitting display panel, liquid crystal display panel and so on or a silicon substrate used by reflective liquid crystal display panel (such as the Liquid Crystal on Wafer (LCOS)). The scan lines 220, the data lines 230 and the active devices 240 are disposed on the substrate 210. The scan lies 220 are disposed in parallel to one another, for example. Similarly, the data lines 230 are also disposed in parallel to one another, for example. However, the scan lines 220 and the data lines 230 can be set in mutually perpendicular directions. Each active device 240 is electrically connected to one of the scan lines 220 and one of the data lines 230. Furthermore, the scan lines 220 and data lines 230 control the operation of the respective active device 240. Furthermore, the active devices 240 can be thin film transistors, for example.

One major aspect of the present invention is that the surface 242 of each active device 240 is not parallel to the surface 212 of the substrate 210. In other words, each active device 240 is set up on the surface 212 of the substrate 210 in a three-dimensional manner. The advantages of the present invention can be explained by referring to FIG. 3. FIG. 3 is a diagram illustrating the principles behind the reduction in the projection areas of non-transparency of an active device on an active device array substrate according to the present invention.

Assume that a conventional active device occupies a width L on the substrate, and the active device of the present invention occupies a width M on the substrate but whose surface has a width S. In the meantime, the included angle between the surface of the active device of the present invention and the surface of the substrate is Θ. The active device of the present invention can reduce the width by ΔL in the X direction compared with a conventional active device. If the required surface width of the active device in the present invention is identical to the surface of a conventional active device, that is, S=L, then ΔL=L−M=L−S×Cos Θ=L(1−Cos Θ). Accordingly, the projection width of the active device of the present invention on the X-axis is smaller than the conventional active device. Therefore, the active device of the present invention can provide more space for incident light coming in a direction perpendicular to the surface of the substrate to pass through. Thus, a display device using the active device array substrate of the present invention can have a larger pixel aperture, thereby improving the quality of the display. In particular, when Θ approaches 90°, the width of the active device in the X-direction is virtually zero.

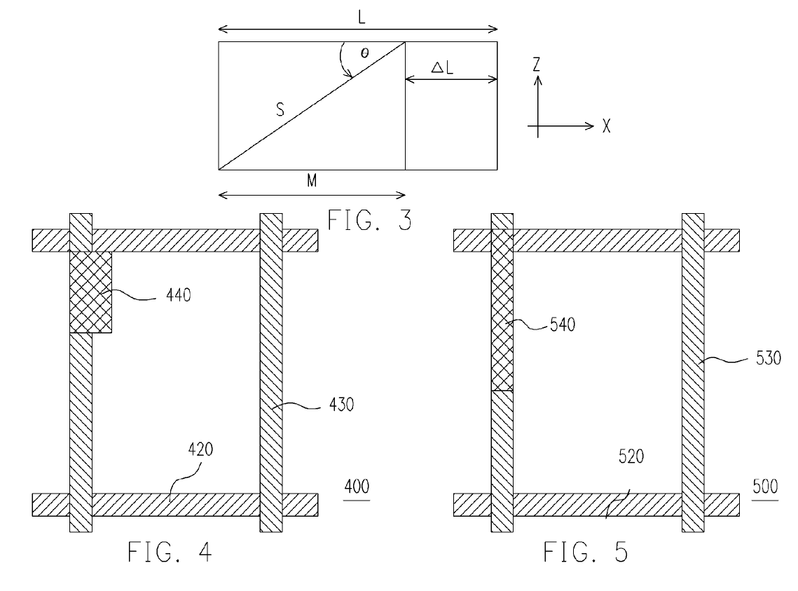

FIGS. 4 and 5 show part of the top views of two different active device array substrate according to the present invention. As shown in FIGS. 4 and 5, the active device array substrates 400 and 500 are almost identical to the active device array substrate 200 shown in FIG. 2A, the only difference is in the location of the active devices 440 and 540. A part of the active device 440 is disposed within the area occupied by the scan line 420 or the data line 430 while the active device 540 is disposed entirely within the area occupied by the scan line 520 or the data line 530. Because the scan lines 420 and 520 and the data lines 430 and 530 are non-transparent, the aforesaid disposition can increase the pixel aperture even further. Furthermore, the active devices 440 and 540 can be configured into a strip-shape.

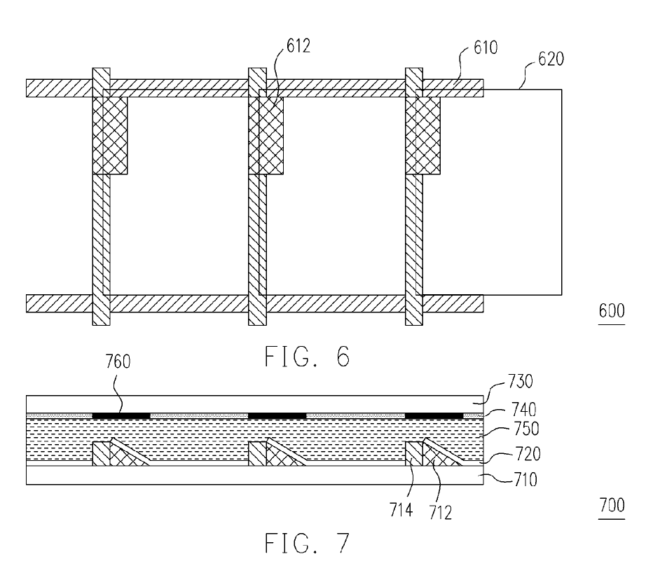

FIG. 6 shows part of the top view of a flat panel display according to one embodiment of the present invention. As shown in FIG. 6, the flat panel display 600 comprises an active device array substrate 610 and a plurality of display elements 620. The active device array substrate 610 can be any one of the active device array substrate in the aforementioned embodiments or other active device array substrate that matches the spirit of the present invention. The display elements 620 can be organic light-emitting diode (OLED) devices or other display devices. The display elements 620 are disposed on the active device array substrate 610 and connected electrically with corresponding active devices 612. If the display elements 620 are OLED devices, each display element 620 comprises an organic light-emitting layer (not shown) sandwiched between a cathode (not shown) and an anode (not shown). In this flat panel display 600, the active devices 612 only cover up a small area. Hence, the pixel aperture of the flat panel display is increased and the quality of the display picture is improved.

FIG. 7 shows a schematic cross-sectional view of part of a liquid crystal display panel according to one embodiment of the present invention. The liquid crystal display panel 700 in the present embodiment comprises an active device array substrate 710, a plurality of pixel electrodes 720, an opposing substrate 730, a common electrode layer 740 and a liquid crystal layer 750. The active device array substrate 710 can be any one of the active device array substrate in the aforesaid embodiments or other active device array substrate that matches the spirit of the present invention. The pixel electrodes 720 are disposed on the active device array substrate 710 and electrically connected to corresponding active devices 712. The opposing substrate 730 is disposed above the active device array substrate 710. The common electrode layer 740 is disposed on the surface of the opposing substrate 730 facing the surface of the active device array substrate 710. The liquid crystal layer 750 is disposed between the active device array substrate 710 and the opposing substrate 730 and located between the common electrode layer 740 and the pixel electrodes 720. The orientation of the molecules in the liquid crystal layer 750 is determined by the voltage differential between the upper common electrode layer 740 and the lower pixel electrodes 720 resulting in some variation of transmissivity of light in various locations. Similarly, because the active devices 712 cover only a small area, the pixel aperture of the liquid crystal display panel 700 is increased and the quality of the picture is improved.

In addition, the liquid crystal display panel 700 may further include a black matrix 760 disposed between the common electrode layer 740 and the opposing substrate 730 and located above the active devices 712, the scan lines (not shown) and the data lines 714. In other words, the non-transparent elements including the active devices 712, the scan lines and the data lines 714 can be disposed within the areas occupied by the black matrix 760 to reduce light shielded areas and increase the pixel aperture of the liquid crystal display panel 700.

In summary, the large aperture flat panel display, liquid crystal display panel and active device array substrate in the present invention have active devices with surfaces incline to or being vertical to the surface of the substrate. Hence, the projection area of the active device on the surface of the substrate is reduced. In this way, the pixel aperture of the liquid crystal display panels and other flat panel displays using this type of active device array substrate is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An active device array substrate, comprising:
a substrate;
a plurality of scan lines disposed on the substrate;
a plurality of data lines disposed on the substrate; and
a plurality of active devices disposed on the substrate, wherein each active device is electrically connected to one of the scan lines and one of the data lines, and the surface of each active device is not parallel to the surface of the substrate.

2. The active device array substrate of claim 1, wherein a part of or all of each active device is disposed within the area occupied by the scan line or the data line.

3. The active device array substrate of claim 1, wherein the active device has a strip-shape.

4. The active device array substrate of claim 1, wherein the active devices include the thin film transistors.

5. A flat panel display, comprising:
an active device array substrate, comprising:
a substrate;
a plurality of scan lines disposed on the substrate;
a plurality of data lines disposed on the substrate;
a plurality of active device disposed on the substrate, wherein each active device is electrically connected to one of the scan lines and one of the data lines, and the surface of each active device is not parallel to the surface of the substrate; and
a plurality of display elements disposed on the active device array substrate and electrically connected to corresponding active devices.

6. The flat panel display of claim 5, wherein a part of or all of each active device is disposed within the area occupied by the scan line or the data line.

7. The flat panel display of claim 5, wherein the active device has a strip-shape.

8. The flat panel display of claim 5, wherein the active device include the thin film transistors.

9. The flat panel display of claim 5, wherein the display elements include the organic light-emitting diode (OLED) devices.

10. A liquid crystal display panel, comprising:
an active device array substrate, having:
a substrate;
a plurality of scan lines disposed on the substrate;
a plurality of data lines disposed on the substrate;
a plurality of active devices disposed on the substrate, wherein each active device is electrically connected to one of the scan lines and one of the data lines, and the surface of each active device is not parallel to the surface of the substrate;
a plurality of pixel electrodes disposed on the active device array substrate and electrically connected to corresponding active devices;
an opposing substrate disposed above the active device array substrate;
a common electrode layer disposed on the surface of the opposing substrate facing the surface of the active device array substrate; and
a liquid crystal layer disposed between the active device array substrate and the opposing substrate and located between the common electrode layer and the pixel electrode.

11. The liquid crystal display panel of claim 10, wherein a part of or all of each active device is disposed within the area occupied by the scan line or the data line.

12. The liquid crystal display panel of claim 10, wherein the active device has a strip-shape.

13. The liquid crystal display panel of claim 10, wherein the active device include the thin film transistors.

14. The liquid crystal display panel of claim 10, further includes a black matrix disposed between the common electrode layer and the opposing substrate and located above the active devices, the scan lines and the data lines.
